(19) United States
(12) Patent Application Publication
(10) Pub. No.: US 2023/0009186 A1
(43) Pub. Date: Jan. 12, 2023

(54) Optical Device

(71) Applicant: Nippon Telegraph and Telephone Corporation, Tokyo (JP)

(72) Inventors: Takuma Tsurugaya, Tokyo (JP); Takuro Fujii, Tokyo (JP); Koji Takeda, Tokyo (JP); Shinji Matsuo, Tokyo (JP)

(21) Appl. No.: 17/783,334

(22) PCT Filed: Dec. 17, 2019
(86) PCT No.: PCT/JP2019/049362

§ 371 Date: Jun. 8, 2022

(51) Int. Cl. G02B 6/122; H01S 5/10; H01S 5/11; H01S 5/042

(52) U.S. Cl. CPC G02B 6/1228; H01S 5/1014; H01S 5/11; H01S 5/04256; G02B 2006/12121

(57) ABSTRACT

In an optical device, a first semiconductor layer and a second semiconductor layer are formed to be thinner than a core, an active layer has a shape with an end in a waveguide direction tapers toward a tip end, the first semiconductor layer having a trapezoidal shape with a width thereof decreases toward a side of a third semiconductor layer from a side of the core in a plan view and a width thereof decreases as one end in the waveguide direction recedes from a central portion of the active region, and the second semiconductor layer having a trapezoidal shape with a width thereof decreases toward a side of a fourth semiconductor layer from the side of the core in a plan view and a width thereof decreases as one end in the waveguide direction recedes from the central portion of the active region.

### CROSS-REFERENCE TO RELATED APPLICATIONS

This application is a national phase entry of PCT Application No. PCT/JP2019/049362, filed on Dec. 17, 2019, which application is hereby incorporated herein by reference.

### TECHNICAL FIELD

The embodiments of the present invention relate to an optical waveguide type optical device.

### BACKGROUND

An optical waveguide type optical device has been researched and developed as a compact and low power consumption active optical device that can be integrated with a silicon substrate on which an electronic circuit or an optical circuit is formed (see NPL 1 to NPL 3). The optical device has a structure in which an active layer is embedded in a core sandwiched from above and below by a clad having a low refractive index such as SiO₂, benzocyclobutene (BCB), or air.

In an optical device having such a type of optical waveguide structure, regarding upper and lower portions of a core in which an active layer is embedded, strong light confinement is realized due to a large difference in refractive index between an InP-based material (refractive index of approximately 3.2 to 3.6) constituting the core and the active layer and a low refractive index material (refractive index of approximately 1 to 1.5) constituting a clad. On the other hand, in a horizontal direction, light is confined due to a relatively small refractive index difference between InP (a refractive index of approximately 3.2) constituting a current injection structure and an active layer (a refractive index of approximately 3.3 to 3.6) of an InP-based mixed crystal. Right and left InP regions sandwiching the core in which the active layer is embedded are subjected to p-type and n-type doping, and thus a current can be injected into the active layer from the horizontal direction.

In general, as a passive InP optical waveguide that does not include an active layer, a channel type structure in which an upper portion and right and left portions of a core are covered with a clad layer formed of the same low refractive index material is used. In a case where the above-mentioned optical device is connected to the optical waveguide, the width (diameter) of a core formed of InP is optimized so that overlapping of waveguide modes therebetween is maximized.

### Citation List

### Non Patent Literature

NPL 1 S. Matsuo et al., “Directly modulated buried heterostructure DFB laser on SiO₂/Si substrate fabricated by regrowth of InP using bonded active layer”, Optics Express, vol. 22, no. 10, pp. 12139-12147, 2014.

NPL 2 T. Hiratani et al., “High-Efficiency Operation of Membrane Distributed-Reflector Lasers on Silicon Substrate”, IEEE Journal of Selected Topics in Quantum Electronics, vol. 23, no. 6, 3700108, 2017.

NPL 3 E. Kanno et al., “Twin-mirror membrane distributed-reflector lasers using 20-μm-long active region on Si substrates”, Optics Express, vol. 26, no. 2, pp. 1268-1277, 2018.

### SUMMARY

### Technical Problem

Incidentally, in the above-mentioned optical device of the related art, light confinement in the horizontal direction is caused by a relatively small refractive index difference, and thus a waveguide mode field extends in the horizontal direction, and a light confinement coefficient of an active layer cannot be increased. Increasing a light confinement coefficient plays an important role in allowing miniaturization, low power consumption, and high performance of optical devices such as by reduction in a threshold value in a laser diode (LD), an increase in the speed of operation during direct modulation, an increase in a gain coefficient in a semiconductor optical amplifier (SOA), and an increase in an absorption coefficient in a photodiode (PD).

Further, in the above-mentioned active optical device, the core is formed of an InP-based compound semiconductor, and the clad in the horizontal direction is formed of InP. However, in the passive optical waveguide, the core is formed of InP, and the clad is formed of a low refractive index material such as air or SiO₂. For this reason, even when the optimization of relative core widths in both the structures has been achieved, a significant mismatching of a mode field remains therebetween. Waveguide mode mismatching between an optical device including an active layer and a passive optical waveguide leads to a loss of scattering into a light radiation mode and unintended reflection of light. Such a state leads to undesired results such as a decrease in an optical resonator Q value in an LD and unintended oscillation due to the formation of a resonator in an SOA.

The embodiments of the present invention are contrived to solve the above-described problems, and an object thereof is to increase light confinement in a region of an active layer in an optical device having an optical waveguide structure.

### Means for Solving the Problem

An optical device according to embodiments of the present invention includes a clad layer, a core constituted by a compound semiconductor formed on the clad layer, an active layer embedded in an active region of the core, a first semiconductor layer and a second semiconductor layer formed on the clad layer to have the active region interposed therebetween and formed in contact with a side surface of the core, the first semiconductor layer being constituted by an n-type compound semiconductor, and the second semiconductor layer being constituted by a p-type compound semiconductor, a third semiconductor layer formed on the clad layer, disposed to have the first semiconductor layer interposed between the third semiconductor layer and the active region, and constituted by an n-type compound semiconductor connected to the first semiconductor layer, a fourth semiconductor layer formed on the clad layer, disposed to have the second semiconductor layer interposed between the fourth semiconductor layer and the active region, and constituted by a p-type compound semiconductor connected to the second semiconductor layer, a first electrode connected to the third semiconductor layer, and a second electrode connected to the fourth semiconductor layer, wherein the first semiconductor layer and the second semiconductor layer are formed to be thinner than the core, the active layer has a shape in which an end in a waveguide direction tapers toward a tip end, the first semiconductor layer includes a first tapered region having a trapezoidal shape in which a width thereof decreases toward a side of the third semiconductor layer from a side of the core when seen in a plan view and a width thereof decreases as an end in the waveguide direction recedes from a central portion of the active region, and the second semiconductor layer includes a second tapered region having a trapezoidal shape in which a width thereof decreases toward a side of the fourth semiconductor layer from the side of the core when seen in a plan view and a width thereof decreases as an end in the waveguide direction recedes from the central portion of the active region.

Effects of the Invention

As described above, according to embodiments of the present invention, a first semiconductor layer and a second semiconductor layer formed to have an active region interposed therebetween are made thinner than a core, and a tapered region is provided in the first semiconductor layer and the second semiconductor layer. Thus, it is possible to increase light confinement in a region of an active layer in an optical device having an optical waveguide structure.

### BRIEF DESCRIPTION OF THE DRAWINGS

FIG. 1A is a cross-sectional view showing a configuration of an optical device according to an embodiment of the present invention.

FIG. 1B is a plan view showing a configuration of the optical device according to the embodiment of the present invention.

FIG. 2A is a diagram showing setting values of simulation used to calculate light confinement.

FIG. 2B is a characteristics diagram showing a base mode of a calculated optical waveguide.

FIG. 3 is a characteristic diagram in which a light confinement coefficient for an active layer 103 is plotted with respect to the thicknesses of a first semiconductor layer 104 and a second semiconductor layer 105.

FIG. 4A is a configuration diagram showing a structure of a connection region which is a simulation target in a case where a channel type InP optical waveguide is connected to a structure in which a core in the related art and semiconductor layers on both sides thereof are made to have the same thickness through abutting and bonding.

FIG. 4B is a distribution chart showing a distribution of light propagating through a connection region in a case where a channel type InP optical waveguide is connected to a structure in which a core in the related art and semiconductor layers on both sides thereof have the same thickness through abutting and bonding.

FIG. 4C is a characteristic diagram in which a power transmittance indicating the proportion of light having been converted into a base mode of an end face of an active layer in light in a base mode which has been incident on the active layer from an end face of a passive optical waveguide is plotted with respect to each of structure parameters, in a case where a channel type InP optical waveguide is connected to a structure in which a core in the related art and semiconductor layers on both sides thereof have the same thickness through abutting and bonding.

FIG. 5A is a configuration diagram showing a structure of a connection region which is a simulation target in a case where a channel type InP optical waveguide and an active region are connected to each other by abutting and bonding in the optical device according to the embodiment.

FIG. 5B is a distribution chart showing a distribution of light propagating through a connection region in a case where the channel type InP optical waveguide and the active region are connected to each other by abutting and bonding in the structure of the optical device according to the embodiment.

FIG. 5C is a characteristic diagram in which a power transmittance representing the proportion of light having been converted into a base mode of an end face of an active layer in light in a base mode which has been incident on the active layer from an end face of a passive optical waveguide is plotted with respect to each of structure parameters, in a case where the channel type InP optical waveguide and the active region are connected to each other by abutting and bonding in the optical device according to the embodiment.

FIG. 6A is a configuration diagram showing a structure of a connection region which is a simulation target in a case where the channel type InP optical waveguide and the active region are connected to each other by abutting and bonding in the structure of the optical device according to the embodiment.

FIG. 6B is a distribution chart showing a distribution of light propagating through a connection region in a case where the channel type InP optical waveguide and the active region are connected to each other by abutting and bonding in the structure of the optical device according to the embodiment.

FIG. 6C is a characteristic diagram in which a power transmittance representing the proportion of light having been converted into a base mode of the end face of the active layer in light in a base mode which has been incident on the active layer from the end face of the passive optical waveguide is plotted with respect to each of structure parameters, in a case where the channel type InP optical waveguide and the active region are connected to each other by abutting and bonding in the structure of the optical device according to the embodiment.

FIG. 7 is a plan view showing a configuration of another optical device according to an embodiment of the present invention.

FIG. 8 is a plan view showing a configuration of another optical device according to an embodiment of the present invention.

### DETAILED DESCRIPTION OF ILLUSTRATIVE EMBODIMENTS

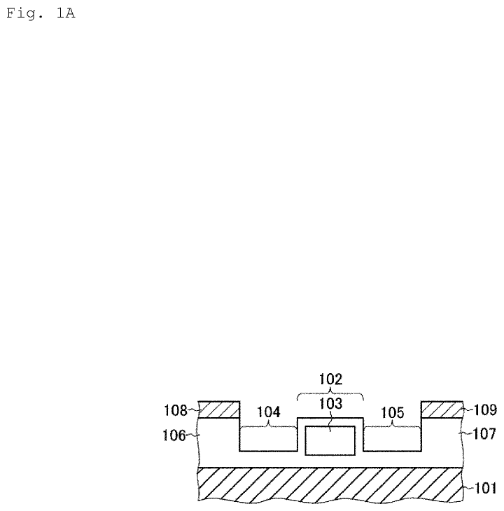

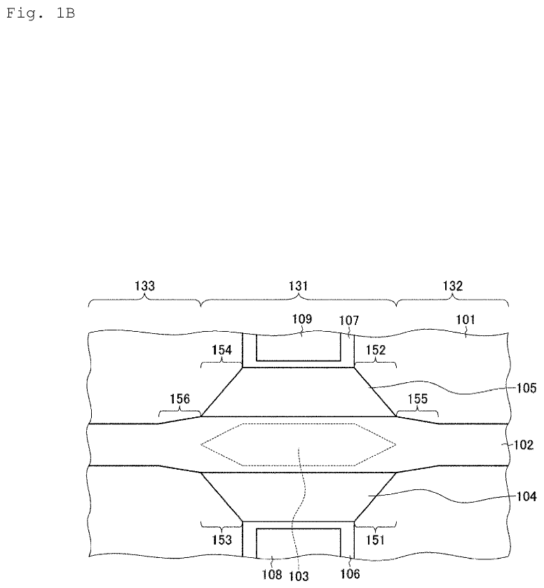

Hereinafter, an optical device according to an embodiment of the present invention will be described with reference to FIG. 1A and FIG. 1B. Meanwhile, FIG. 1A shows a cross-section of a surface perpendicular to a waveguide direction.

The optical device includes a clad layer 101, a core 102 formed on the clad layer 101, an active layer 103 embedded in the core 102, and a first semiconductor layer 104 and a second semiconductor layer 105 that are formed on the clad layer 101, are formed to have an active region 131 interposed therebetween in a direction parallel to the surface of the clad layer 101 and perpendicular to the waveguide direction, and are formed to be in contact with the side surface of the core 102.

The clad layer 101 is constituted by, for example, silicon oxide. For example, a silicon oxide layer formed on a substrate such as Si can be configured as the clad layer 101. The core 102 may be constituted by a Group III-V compound semiconductor such as InP. For example, the core 102 can be formed by depositing InP on the clad layer 101 by a well-known organic metal vapor phase growth method or the like.

The active layer 103 is embedded in the active region 131 of the core 102. The extremal form of the active layer 103 is, for example, a rectangular parallelepiped. In addition, the first semiconductor layer 104 and the second semiconductor layer 105 are disposed with the active region 131 interposed therebetween. The first semiconductor layer 104 is constituted by an n-type Group III-V compound semiconductor such as n-type InP. In addition, the second semiconductor layer 105 is constituted by a p-type Group III-V compound semiconductor such as p-type InP.

In addition, the optical device includes a third semiconductor layer 106 formed on the clad layer 101, disposed such that the first semiconductor layer 104 is interposed between the third semiconductor layer 106 and the active region 131, and connected to the first semiconductor layer 104, and also includes a fourth semiconductor layer 107 formed on the clad layer 101, disposed such that the second semiconductor layer 105 is interposed between the fourth semiconductor layer 107 and the active region 131, and connected to the second semiconductor layer 105. The third semiconductor layer 106 is constituted by an n-type Group III-V compound semiconductor such as n-type InP. In addition, the fourth semiconductor layer 107 is constituted by a p-type Group III-V compound semiconductor such as p-type InP.

In addition, the optical device includes a first electrode 108 electrically connected to the third semiconductor layer 106, and a second electrode 109 electrically connected to the fourth semiconductor layer 107. Meanwhile, in this example, when the side of the clad layer 101 is set to be a lower side, air is a clad on the upper side of the core 102.

In addition to the above-described configuration, first, the optical device according to the embodiment is configured such that the first semiconductor layer 104 and the second semiconductor layer 105 are formed to be thinner than the core 102. Meanwhile, in this example, the core 102, the first semiconductor layer 104, the second semiconductor layer 105, the third semiconductor layer 106, and the fourth semiconductor layer 107 are formed integrally.

Further, in the optical device according to the embodiment, the active layer 103 has a shape in which an end thereof in a waveguide direction tapers toward the tip end thereof. In this example, the active layer 103 has a shape in which both ends thereof in the waveguide direction taper. Meanwhile, the waveguide direction is a right-left direction of the paper in FIG. 1B.

Further, in the optical device according to the embodiment, the first semiconductor layer 104 includes a first tapered region 151 having a trapezoidal shape in which the width thereof decreases toward the side of the third semiconductor layer 106 from the side of the core 102 when seen in a plan view and the width thereof decreases as an end in the waveguide direction recedes from the central portion of the active region 131. Similarly, the second semiconductor layer 105 includes a second tapered region 152 having a trapezoidal shape in which the width thereof decreases toward the side of the fourth semiconductor layer 107 from the side of the core 102 when seen in a plan view and the width thereof decreases as an end in the waveguide direction recedes from the central portion of the active region 131.

Further, in this example, the first semiconductor layer 104 includes a third tapered region 153 in which the width thereof decreases as the other end in the waveguide direction recedes from the central portion of the active region 131. Similarly, the second semiconductor layer 105 includes a fourth tapered region 154 in which the width thereof decreases as the other end in the waveguide direction recedes from the central portion of the active region 131. In this example, the first semiconductor layer 104 and the second semiconductor layer 105 have an isosceles trapezoidal shape in which the side of the active layer 103 is the base when seen in a plan view.

Further, in the optical device according to the embodiment, the core 102 includes a fifth tapered region 155 at one end of the active region 131, the fifth tapered region 155 being configured such that the width thereof decreases as a distance from the active region 131 increases when seen in a plan view. In addition, the core 102 includes a sixth tapered region 156 at the other end of the active region 131, the sixth tapered region 156 being configured such that the width thereof decreases as a distance from the active region 131 increases when seen in a plan view. In this example, the passive optical waveguide 132 and the passive optical waveguide 133 that are disposed with the active region 131 interposed therebetween in the waveguide direction are optically connected to the active layer 103 (active region 131) through the fifth tapered region 155 and the sixth tapered region 156. Meanwhile, the widths of the cores of the passive optical waveguide 132 and the passive optical waveguide 133 can also be set to be the same as the width of the core of the active region 131.

When the manufacture of the above-mentioned structure is described briefly, for example, a thin semiconductor layer formed of InP is formed on the clad layer 101, and then an InP-based semiconductor layer or a semiconductor laminated structure serving as the active layer 103 is formed thereon. The semiconductor laminated structure is, for example, a multiple quantum well structure. Thereafter, the active layer 103 is formed by patterning the InP-based semiconductor layer or the semiconductor laminated structure serving as the active layer 103 by known lithography technology and etching technology.

Next, InP is regrown from the thin semiconductor layer formed of InP and exposed in the vicinity of the active layer 103 by forming the active layer 103 to form a thick semiconductor layer in which the active layer 103 is embedded, and impurities are injected to form each conductive type region. Next, regions that become the first semiconductor layer 104 and the second semiconductor layer 105 and regions that become the third semiconductor layer 106 and the fourth semiconductor layer 107 are formed by known lithography technology and etching technology. In this step, the shapes of the cores 102 of the passive optical waveguide 132 and the passive optical waveguide 133 and the cores 102 of the fifth tapered region 155 and the sixth tapered region 156 are formed. In the passive optical waveguide 132, the passive optical waveguide 133, the fifth tapered region 155, and the sixth tapered region 156, all of InP (semiconductor) in regions other than the core 102 are removed to expose the upper surface of the clad layer 101.

Thereafter, a groove is formed in each of the regions that become the first semiconductor layer 104 and the second semiconductor layer 105 to make the layers thin by known lithography technology and etching technology, and thus it is possible to form the first semiconductor layer 104 and the second semiconductor layer 105, and the third semiconductor layer 106 and fourth semiconductor layer 107 that are subsequent thereto. In this case, an optical waveguide referred to as a so-called rib type is formed.

Meanwhile, after a groove is formed in each of the regions that become the first semiconductor layer 104 and the second semiconductor layer 105 to make the layers thin, the regions that become the first semiconductor layer 104 and the second semiconductor layer 105 and the regions that become the third semiconductor layer 106 and the fourth semiconductor layer 107 can also be formed. In the active region 131, the first semiconductor layer 104 and the second semiconductor layer 105 with the core 102 interposed therebetween are thinner than the core 102, and thus light confinement with respect to the core 102 in a direction parallel to the surface of the clad layer 101 and perpendicular to the waveguide direction can be increased compared with in the case of these having the same thickness.

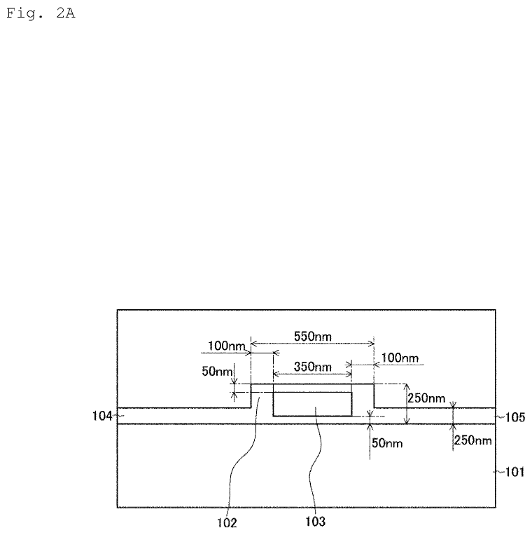

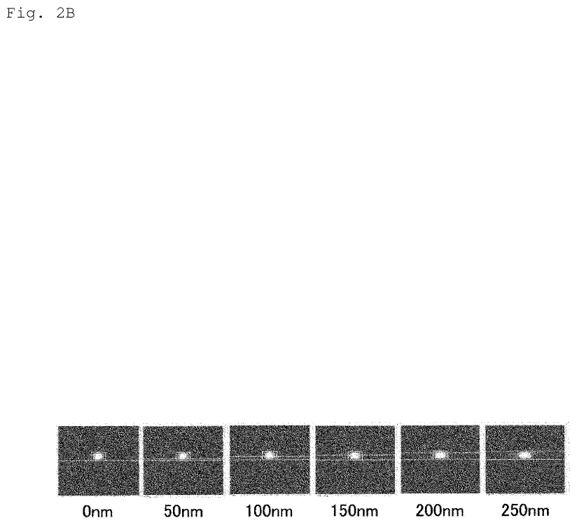

Regarding effects of the light confinement, simulation results will be described below. FIG. 2A shows setting values of simulation used to calculate light confinement. In addition, FIG. 2B shows a base mode of a calculated optical waveguide. Numbers in FIG. 2B indicate the thicknesses of the first semiconductor layer 104 and the second semiconductor layer 105.

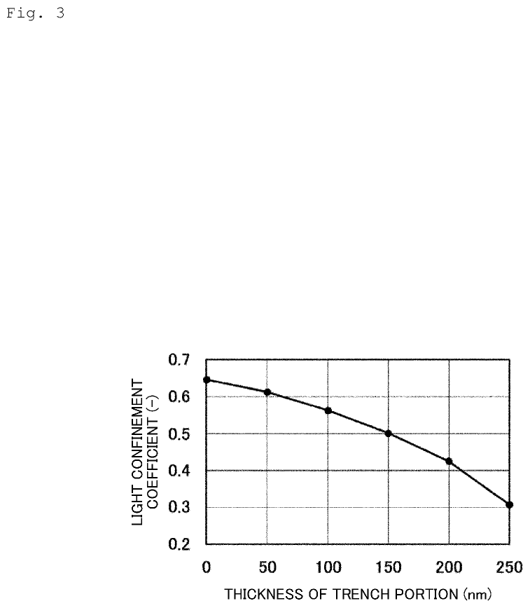

As shown in FIG. 2B, it can be understood that as the first semiconductor layer 104 and the second semiconductor layer 105 become thinner, a mode field is more strongly confined in the core 102 (active layer 103) in the active region 131. FIG. 3 is a diagram in which a light confinement coefficient for the active layer 103 is plotted with respect to the thicknesses of the first semiconductor layer 104 and the second semiconductor layer 105. In the simulation example, a thickness of 250 nm is the same thickness as the core 102. It can be understood that approximately double the light confinement is obtained as compared to the case of the same thickness as the core 102 by thinning the first semiconductor layer 104 and the second semiconductor layer 105 to 50 nm.

Localization of a mode field also brings a desirable effect from the viewpoint of reducing element resistance. That is, in the optical waveguide type current injection optical device, when a mode field of an optical waveguide has a portion overlapping the portion of an electrode, a large light loss due to this is caused. For this reason, it is important to pull the electrode away from the core until the mode field is not affected by its presence. In this regard, in an optical device of the related art in which a core and semiconductor layers on both sides of the core have the same thickness, a mode field extends in a horizontal direction as described above, and thus it is necessary to dispose an electrode at a remote location correspondingly.

On the other hand, according to the optical device according to the embodiment, a mode field is also strongly localized in the horizontal direction, and thus the first electrode 108 and the second electrode 109 can be brought close to the core 102. In an active optical device constituted by p-type InP, an InP-based active layer, and n-type InP, p-type InP has a particularly large resistivity, and the element resistance is controlled by a doping concentration and shape of the p-type InP region. According to the embodiment, the p-type second semiconductor layer 105 is thinner than the core 102, and thus the resistance of this region increases. On the other hand, the first electrode 108 and the second electrode 109 can be brought close to the core 102, and thus an increase in a resistance value due to the thinning can be offset by a reduction in the length of a conduction path. As a result, it is possible to realize element resistance at the same level or lower than in the related art in which a core and semiconductor layers have the same thickness.

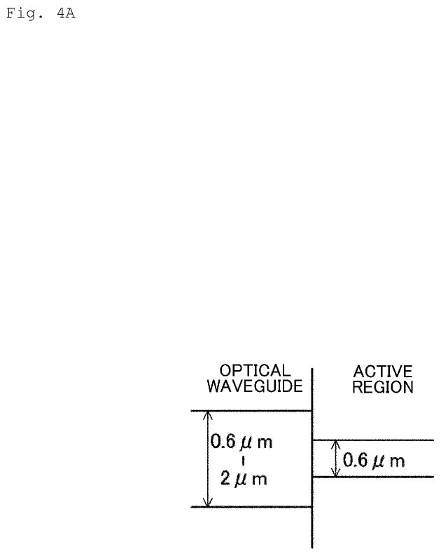

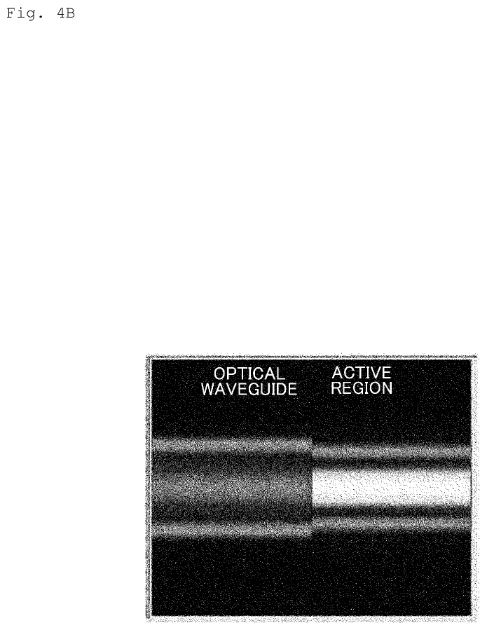

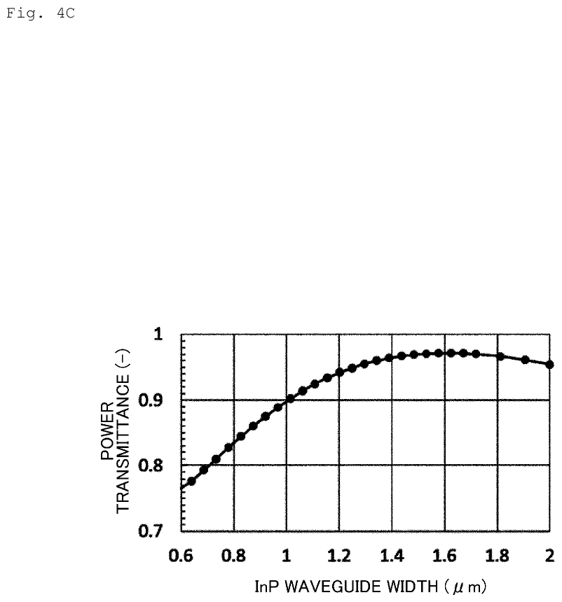

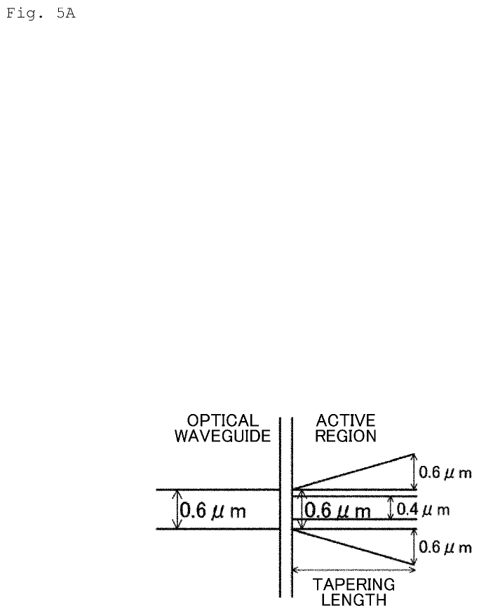

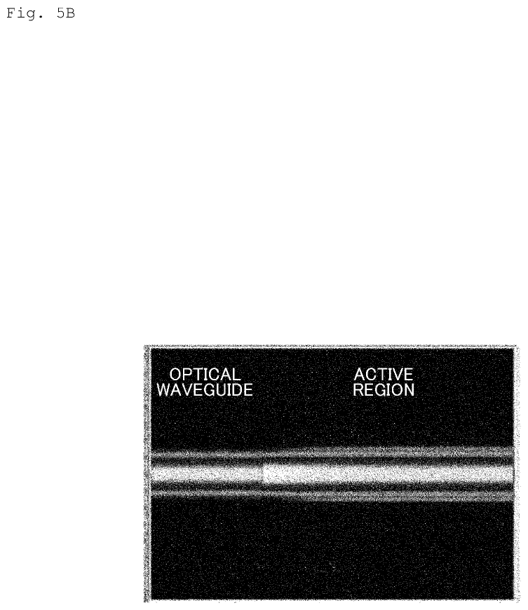

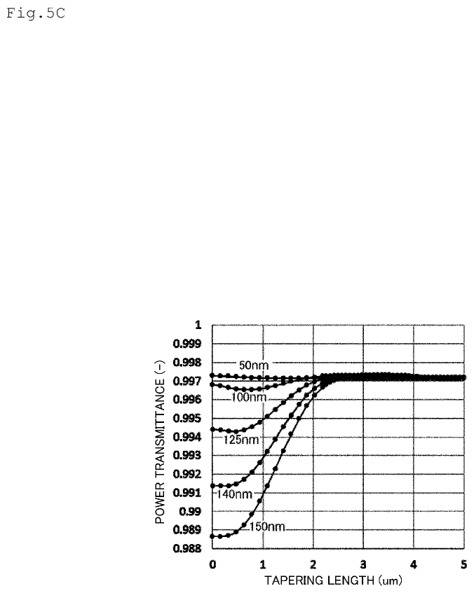

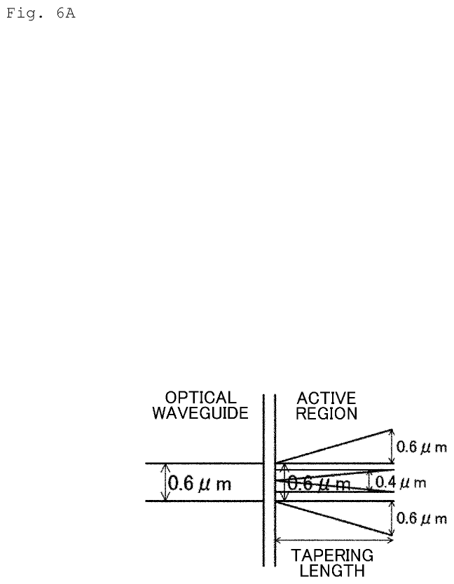

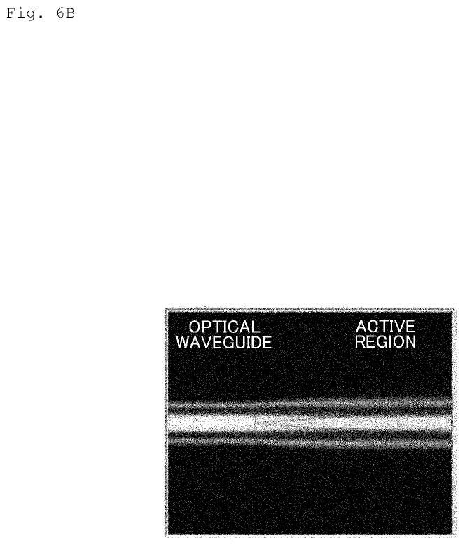

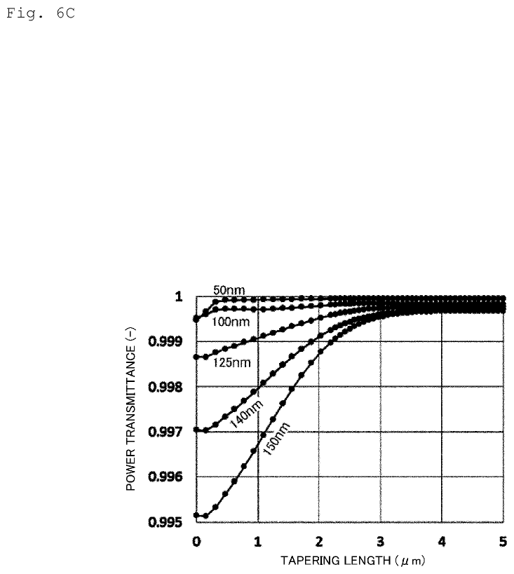

Next, calculation results related to optical connection between the active region 131, the passive optical waveguide 132, and the passive optical waveguide 133 will be described with reference to FIG. 4A, FIG. 4B, FIG. 4C, FIG. 5A, FIG. 5B, FIG. 5C, FIG. 6A, FIG. 6B, and FIG. 6C. FIG. 4A, FIG. 5A, and FIG. 6A show a structure of a connection region of a simulation target. FIG. 4B, FIG. 5B, and FIG. 6B show distribution of light propagating through a connection region. FIG. 4C, FIG. 5C, and FIG. 6C are diagrams in which a power transmittance indicating the proportion of light having been converted into a base mode of an end face of an active layer in light in a base mode which has been incident on the active layer from an end face of a passive optical waveguide is plotted with respect to each of structure parameters. In addition, numerical values inserted in FIG. 5C and FIG. 6C indicate the thicknesses of the first semiconductor layer 104 and the second semiconductor layer 105.

FIG. 4A, FIG. 4B, and FIG. 4C show a case where a channel type InP optical waveguide is connected to a structure in which a core in the related art and semiconductor layers on both sides thereof have the same thickness through abutting and bonding. In this simulation example, the width of the embedded active layer is set to 0.6 μm. However, regarding dimensions for obtaining the highest mode conversion efficiency in this condition, the width of the core of the InP optical waveguide is set to approximately 1.6 μm, and a power transmittance in this case is 97.2%. That is, this means that the remaining 2.8% of the power has been lost as reflected light, synchrotron radiation, and the like.

On the other hand, FIG. 5A, FIG. 5B, FIG. 5C, FIG. 6A, FIG. 6B, and FIG. 6C show the optical device according to the embodiment, and the active region 131 is optically connected to the passive optical waveguide 132 and the passive optical waveguide 133. Meanwhile, in this example, the widths of the first semiconductor layer 104 and the second semiconductor layer 105 at a right end are set to 0.6 μm, but this is wide enough for light in a base mode of the active region 131 not to be affected by outer regions (the first electrode 108 and the second electrode 109) in this setup.

First, in FIG. 5A, FIG. 5B, and FIG. 5C, the widths of the cores 102 are the same in the active region 131, the passive optical waveguide 132, and the passive optical waveguide 133. FIG. 5C shows the dependence of a power transmittance on the thicknesses of the first semiconductor layer 104 and the second semiconductor layer 105, and tapering lengths of the first tapered region 151, the second tapered region 152, the third tapered region 153, and the fourth tapered region 154. From this dependence, it can be understood that the thinning and tapering of the first semiconductor layer 104 and the second semiconductor layer 105 significantly improve optical connectivity between the active region 131, the passive optical waveguide 132, and the passive optical waveguide 133. In particular, in a case where the first semiconductor layer 104 and second semiconductor layer 105 have a thickness equal to or less than 100 nm, an extremely high power transmittance of 99.6% or more is obtained even when the tapering length is only several hundreds of nm. This is a high transmittance that cannot be obtained in the related art.

On the other hand, it can also be seen that the power transmittance tends to remain high at approximately 99.7% no matter how long the tapering length is. This is due to the non-insulating presence of the rectangular active layer 103 between the active region 131, the passive optical waveguide 132 and the passive optical waveguide 133. In FIG. 6A, FIG. 6B, and FIG. 6C, the active layer 103 is tapered to have a shape in which an end in the waveguide direction tapers toward a tip end. As a result, when the first semiconductor layer 104 and the second semiconductor layer 105 have a thickness of 100 nm or less and a tapering length of several hundreds of nm, an extremely high power transmittance exceeding 99.9% is obtained between the active region 131, the passive optical waveguide 132, and the passive optical waveguide 133.

As can be understood from the above-described simulation results, in the optical device according to the embodiment of the present invention, the passive optical waveguide 132 and the passive optical waveguide 133 based on a channel type optical waveguide which is often used as an InP-based passive optical waveguide can be connected to the active region 131 extremely efficiently by an extremely short tapered region having a length of only several hundreds of nm.

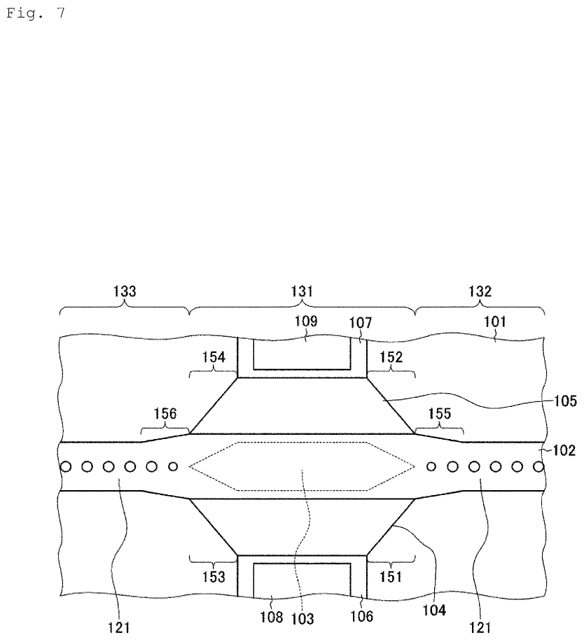

Next, another optical device according to an embodiment of the present invention will be described with reference to FIG. 7. For example, in the optical device according to the embodiment, a resonator can be constituted by a reflecting portion constituted by a photonic crystal structure 121 formed to have an active region 131 interposed therein in the waveguide direction as shown in FIG. 7, and can be used as a laser. The photonic crystal structure 121 is a structure in which a plurality of through-holes penetrating cores 102 are arranged in a thickness direction in the cores 102 of a passive optical waveguide 132 and a passive optical waveguide 133. Meanwhile, diffraction gratings may be formed on the cores 102 of the passive optical waveguide 132 and the passive optical waveguide 133 instead of the photonic crystal structure 121, and these may be used as reflecting portions when configuring a resonator.

As described above, by adopting a structure in which the resonators (reflecting portions) are formed, the active region 131 is sandwiched between the reflecting portions, and light is confined in the active region, it is possible to make the optical device operate as a current injection laser. As a mechanism for extracting light, for example, the number of cycles of the photonic crystal structure 121 of the passive optical waveguide 132 can be reduced, and accordingly transmitted components can be output. In addition, for example, it is also possible to form a Si core disposed close to the core 102 of the passive optical waveguide 132 within a range where optical coupling can be performed, and to take out oscillation light by an optical waveguide formed by the Si core.

In the optical device according to the embodiment, a light confinement coefficient of the active region 131 with respect to the active layer 103 is high, and thus it is possible to achieve a decrease in an oscillation threshold value and a high-speed operation during direct modulation. In particular, in a short resonator laser, the proportion of light leaking out into a region of the reflecting portion becomes relatively high, and thus it is important to realize a light confinement coefficient as high as possible in the active layer 103. Further, in the optical device according to the embodiment, since matching of a mode field between the active region 131 and a mirror portion (the passive optical waveguide 132 and the passive optical waveguide 133) is excellent, a radiation loss due to mode mismatching is reduced, and thus it is possible to suppress a reduction in a resonator Q value due to a radiation loss. The radiation loss scales in inverse proportion to the length of the resonator, and thus a reduction in a radiation loss is particularly effective in realizing a low threshold oscillation of a short resonator laser.

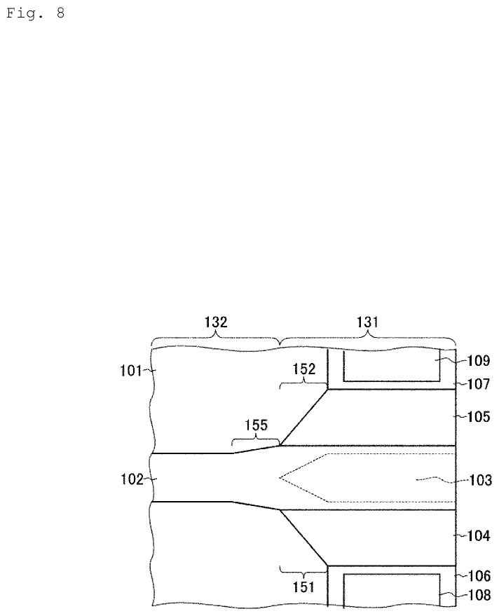

Next, another optical device according to an embodiment of the present invention will be described with reference to FIG. 8. The optical device is configured such that the passive optical waveguide 133 of the optical device described using FIG. 1Bis not provided, and the passive optical waveguide 132 is connected. In this configuration, the passive optical waveguide 132 is connected to one end side of an active region 131, and the other end of the active region 131 is terminated. In this configuration, a voltage applied to the active layer 103 is set to zero bias or reverse bias, and an optical signal desired to be received can be operated as a photodiode by being guided and input to the active region 131.

In the optical device according to the embodiment, since a light confinement coefficient in the active region 131 is high, it is possible to efficiently receive an optical signal by a shorter active layer length, and thus the miniaturization of the optical device, and a high-speed operation due to a reduction in capacitance accompanying a reduction in the length of the active layer are achieved. In addition, a radiation loss between the passive optical waveguide 132 and the active region 131 is reduced, and thus a signal can be received with higher efficiency.

In addition, the optical device according to the embodiment can also be used as a semiconductor optical amplifier. After an inverted distribution is generated by injecting a current into the active layer 103, an optical signal desired to be amplified is input, for example, from the passive optical waveguide 132 to the active region 131. Thereby, the optical signal amplified by induced emission from the active layer 103 is output to the side of the passive optical waveguide 133. As features of the optical amplifier, a light confinement coefficient for the active layer 103 in the active region 131 is high, and thus it is possible to efficiently amplify an optical signal with a shorter active layer length, thereby exhibiting effects of the miniaturization and low power consumption of the optical device. Further, in the semiconductor optical amplifier, an oscillation operation due to unintended reflection at an interface between different structures often becomes a problem. However, according to the embodiment, the above-described undesirable oscillation operation can be effectively suppressed by excellent mode matching between the passive optical waveguide 132, the passive optical waveguide 133, and the active region 131.

As described above, according to embodiments of the present invention, since a first semiconductor layer and a second semiconductor layer formed to have an active region interposed therebetween are made thinner than a core, and a tapered region is provided in the first semiconductor layer and the second semiconductor layer, it is possible to further increase light confinement in a region of the active layer in an optical device having an optical waveguide structure. According to embodiments of the present invention, light confinement which is stronger than that in the related art is obtained. In addition, an electrode can be brought close to the active layer due to light being strongly confined in a horizontal direction, and element resistance is reduced. Further, a mode field in the active region (active layer) is brought close to a mode field of a passive optical waveguide, and thus both the mode fields can be connected to each other by a short tapered structure with high heat insulation.

A strong light confinement in the active layer brings a lower threshold value in a semiconductor laser, a high-speed modulation operation, miniaturization of a semiconductor optical amplifier, low power consumption, miniaturization of a photodiode, and a high-speed operation. A reduction in element resistance can suppress the generation of Joule's heat during the injection of a current and can make it possible to perform a high injection operation in the semiconductor laser and the semiconductor optical amplifier. Highly efficient mode conversion between the active region and the passive optical waveguide region reduces a threshold value in the semiconductor laser (particularly, a semiconductor laser having a short resonator), suppresses an unintended oscillation operation in semiconductor optical amplifier, and increase quantum efficiency in a photodiode.

Meanwhile, the embodiments of the present invention are not limited to the above-described embodiments, and it is apparent that various modifications and combinations can be made by one skilled in the art within the technical idea of the embodiments of the present invention.

### REFERENCE SIGNS LIST

101 Clad layer

102 Core

103 Active layer

104 First semiconductor layer

105 Second semiconductor layer

106 Third semiconductor layer

107 Fourth semiconductor layer

108 First electrode

109 Second electrode

131 Active region

132 Passive optical waveguide

133 Passive optical waveguide

151 First tapered region

152 Second tapered region

153 Third tapered region

154 Fourth tapered region

155 Fifth tapered region

156 Sixth tapered region

1-7. (canceled)

8. An optical device comprising:
a clad layer;
a core comprising a compound semiconductor on the clad layer;
an active layer embedded in an active region of the core;
a first semiconductor layer and a second semiconductor layer on the clad layer, the active region being between the first semiconductor layer and the second semiconductor layer and in contact with a side surface of the core, the first semiconductor layer comprising an n-type compound semiconductor, and the second semiconductor layer comprising a p-type compound semiconductor;
a third semiconductor layer on the clad layer, the first semiconductor layer being between the third semiconductor layer and the active region, the third semiconductor layer comprising an n-type compound semiconductor connected to the first semiconductor layer;
a fourth semiconductor layer on the clad layer, the second semiconductor layer being between the fourth semiconductor layer and the active region, the fourth semiconductor layer comprising a p-type compound semiconductor connected to the second semiconductor layer;
a first electrode connected to the third semiconductor layer; and
a second electrode connected to the fourth semiconductor layer,
wherein the first semiconductor layer and the second semiconductor layer are thinner than the core,
the active layer has a shape in which an end in a waveguide direction tapers toward a tip end,
the first semiconductor layer includes a first tapered region having a trapezoidal shape in which a width thereof decreases toward a side of the third semiconductor layer from a side of the core in a plan view, and
the second semiconductor layer includes a second tapered region having a trapezoidal shape in which a width thereof decreases toward a side of the fourth semiconductor layer from the side of the core in a plan view.

9. The optical device according to claim 8, wherein
a width of the first semiconductor layer decreases as an end in the waveguide direction recedes from a central portion of the active region.

10. The optical device according to claim 9, wherein
a width of the second semiconductor layer decreases as an end in the waveguide direction recedes from a central portion of the active region.

11. The optical device according to claim 10, wherein
the first semiconductor layer includes a third tapered region in which a width thereof decreases as the other end in the waveguide direction recedes from the central portion of the active region, and
the second semiconductor layer includes a fourth tapered region in which a width thereof decreases as the other end in the waveguide direction recedes from the central portion of the active region.

12. The optical device according to claim 8, wherein
the core includes a fifth tapered region at one end of the active region, the fifth tapered region being configured such that a width thereof decreases as a distance from the active region increases in a plan view.

13. The optical device according to claim 12, wherein
the core includes a sixth tapered region at the other end of the active region, the sixth tapered region being configured such that a width thereof decreases as a distance from the active region increases in a plan view.

14. The optical device according to claim 8, further comprising:
a resonator with the active region interposed therein in the waveguide direction.

15. The optical device according to claim 14, wherein
the resonator comprises a photonic crystal structure formed in the core.

16. The optical device according to claim 14, wherein
the resonator comprises a diffraction grating formed on the core.

17. A method of forming an optical device, the method comprising:
forming a core comprising a compound semiconductor on a clad layer;
forming an active layer embedded in an active region of the core;
forming a first semiconductor layer and a second semiconductor layer on the clad layer, the active region being between the first semiconductor layer and the second semiconductor layer and in contact with a side surface of the core, the first semiconductor layer comprising an n-type compound semiconductor, and the second semiconductor layer comprising a p-type compound semiconductor;
forming a third semiconductor layer on the clad layer, the first semiconductor layer being between the third semiconductor layer and the active region, the third semiconductor layer comprising an n-type compound semiconductor connected to the first semiconductor layer;
forming a fourth semiconductor layer on the clad layer, the second semiconductor layer being between the fourth semiconductor layer and the active region, the fourth semiconductor layer comprising a p-type compound semiconductor connected to the second semiconductor layer;
forming a first electrode connected to the third semiconductor layer; and
forming a second electrode connected to the fourth semiconductor layer,
wherein the first semiconductor layer and the second semiconductor layer are thinner than the core,
the active layer has a shape in which an end in a waveguide direction tapers toward a tip end,
the first semiconductor layer includes a first tapered region having a trapezoidal shape in which a width thereof decreases toward a side of the third semiconductor layer from a side of the core in a plan view, and
the second semiconductor layer includes a second tapered region having a trapezoidal shape in which a width thereof decreases toward a side of the fourth semiconductor layer from the side of the core in a plan view.

18. The method of claim 17, wherein forming the active layer embedded in the active region of the core comprises:
forming a first InP layer on the clad layer;
forming an InP-based semiconductor layer on the first InP layer;
patterning the InP-based semiconductor layer to form the active layer; and
growing a second InP layer on the first InP layer and the patterned InP-based layer.

19. The method of claim 17, wherein forming the active layer embedded in the active region of the core comprises:
forming a first InP layer on the clad layer;
forming a laminated semiconductor structure on the first InP layer;
patterning the laminated semiconductor structure to form the active layer; and
growing a second InP layer on the first InP layer and the patterned laminated semiconductor structure.

20. The method of claim 19, wherein the laminated semiconductor structure comprises a multiple quantum well structure.
